(19) United States
(12) Patent Application Publication
(10) Pub. No.: US 2006/0073670 A1
(43) Pub. Date: Apr. 6, 2006

(54) Method of manufacturing a semiconductor device

(76) Inventors: Yong-Kug Bae, Gyeonggi-do (KR); Kwang-Sub Yoon, Seoul (KR); Young-Wook Park, Gyeonggi-do (KR); Jung-Hyeon Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/243,397

(22) Filed: Oct. 3, 2005

(30) Foreign Application Priority Data
Oct. 1, 2004 (KR) 2004-78162

(51) Int. Cl. H01L 21/20; H01L 21/4763; H01L 21/8242

(52) U.S. Cl. 438/396; 438/253; 438/631; 438/633

(57) ABSTRACT

In one embodiment, first and second multi-layer pattern structures are formed over first and second regions of a substrate, respectively. The first and second multi-layer pattern structures include first and second support layer patterns, respectively. The first and second multi-layer pattern structures define first and second openings, respectively. The first and second openings partially expose a portion of the first region and a portion of the second region, respectively. First and second liner patterns are formed on an inner face of the first opening and an inner face of the second opening, respectively. A first etching process is performed on the first multi-layer pattern structure until the first support layer pattern is removed. A second etching process is performed to remove the second multi-layer pattern structure except for the second support layer pattern.

### CROSS REFERENCE TO RELATED APPLICATION

This application claims benefit of priority under 35 USC § 119 from Korean Patent Application No. 2004-78162 filed on Oct. 1, 2004, the disclosure of which is incorporated herein by reference in its entirety.

### BACKGROUND OF THE INVENTION

1. Field of the Invention

Example embodiments of the present invention relate to methods of manufacturing a semiconductor device. More particularly, example embodiments of the present invention relate to methods of manufacturing a lower electrode having a cylindrical structure.

2. Description of the Related Art

Semiconductor devices continue to be highly integrated so that the size of a unit cell of the semiconductor device continues to shrink. This causes the capacitance of a capacitor formed in the unit cell to be increasingly small. Capacitors have been developed to have a cylindrical structure. These capacitors generally have a lower electrode and an upper electrode, as well as a capacitor dielectric disposed between the lower electrode and the upper electrode. This cylindrical structure enables the capacitor to have a relatively large capacitance, despite its overall small size.

Problems can occur when the aspect ratio of the lower electrode having the cylindrical shape is very high: the lower electrode may easily lean or bend by external factors such as thermal stress applied to the lower electrode in subsequent processes, for example. When this happens, the lower electrodes may electrically connect to each other, causing a short. Thus, the reliability of the semiconductor device including these lower electrodes may decrease.

As a recent solution, a stabilizing member interposed between the lower electrodes of adjacent capacitors is placed to prevent the lower electrode from leaning or bending.

Examples of conventional methods for forming the stabilizing member are disclosed in U.S. Patent Application Publication No. 2003-178728, Korean Patent Laid-open Publication No. 2003-69272, Korean Patent Laid-open Publication No. 2001-76008, to name a few. In accordance with the conventional methods, a multi-layer pattern structure including a support layer pattern is formed on a substrate. The multi-layer pattern structure has an opening. The multi-layer pattern structure may operate as a mold structure pattern used for forming a lower electrode. A conductive layer is formed on an upper face of the multi-layer pattern structure and an inner face of the opening. An upper portion of the conductive layer is removed by a planarization process so that a conductive layer pattern may be formed in the opening. Subsequently, an etching process using a difference in etch rate is carried out so that the multi-layer pattern structure may be removed except for the support layer pattern. Here, the conductive layer pattern corresponds to the lower electrode. The support layer pattern corresponds to a stabilizing member.

However, the thickness uniformity of the stabilizing member formed by the conventional methods is relatively low. That is, the difference in thickness between a central portion of the stabilizing member and a peripheral portion of the stabilizing member may be relatively large. Thus, the stabilizing member may not efficiently support the lower electrodes. The etching process that uses the difference in etch rate may cause damage to the support layer pattern corresponding to the stabilizing member. Also, the support layer pattern corresponding to the stabilizing member is damaged during removing of residues of the multi-layer pattern structure.

FIG. 1 is an SEM picture illustrating conventional lower electrodes positioned over a central portion of the substrate. FIG. 2 is an SEM picture illustrating conventional lower electrodes positioned over a peripheral portion of the substrate.

Referring to FIGS. 1 and 2, conventional lower electrodes are uniformly supported by the stabilizing member over the central portion of the substrate. However, conventional lower electrodes are hardly supported by the stabilizing member over the peripheral portion of the substrate. It is because the stabilizing member is damaged in the peripheral portion of the substrate more than in the central portion of the substrate.

Thus, the conventional lower electrodes may lean or bend, in the peripheral portion of the substrate more so than the central portion of the substrate.

For these reasons the conventional lower electrode formed by the conventional method may have electrical failures.

### SUMMARY OF THE INVENTION

Some example embodiments of the present invention provide methods of manufacturing a semiconductor device having a cylindrical pattern supported by a stabilizing member that has a substantially uniform thickness.

Further example embodiments of the present invention provide methods of manufacturing a semiconductor device having a lower electrode supported by a stabilizing member that has a substantially uniform thickness.

In one embodiment, first and second multi-layer pattern structures are formed over first and second regions of a substrate, respectively. The first and second multi-layer pattern structures include first and second support layer patterns, respectively. The first and second multi-layer pattern structures define first and second openings, respectively. The first and second openings expose at least a portion of the first region and at least a portion of the second region, respectively. First and second liner patterns are formed on an inner face of the first opening and an inner face of the second opening, respectively. A first etching process is performed on the first multi-layer pattern structure until the first support layer pattern is removed. A second etching process is performed to remove the second multi-layer pattern structure except for the second support layer pattern.

Thus, among others, damage to a stabilizing member formed by etching a support layer pattern may be efficiently reduced. It may be because the second etching process is performed on only some regions of the substrate rather than the entire substrate. In addition, because the stabilizing member has a relatively small area, residues remaining on the stabilizing member may be efficiently removed without damage to the stabilizing member.

### BRIEF DESCRIPTION OF THE DRAWINGS

The above and other advantages of the present invention will become readily apparent by reference to the following detailed description when considered in conjunction with the accompanying drawings in which:

FIG. 1 is an SEM picture illustrating conventional lower electrodes positioned over a central portion of the substrate;

FIG. 2 is an SEM picture illustrating conventional lower electrodes positioned over a peripheral portion of the substrate;

FIGS. 3A to 3I are cross-sectional views illustrating methods of manufacturing a semiconductor device in accordance with example embodiments of the present invention;

FIG. 4 is a plan view of FIG. 3D for illustrating a first region and a second region;

FIG. 5 is a plan view of FIG. 3G for illustrating a photoresist pattern used in a first etching process; and

FIG. 6 is a plan view of FIG. 3I for illustrating a first lower electrode and a second lower electrode that is supported by a stabilizing member.

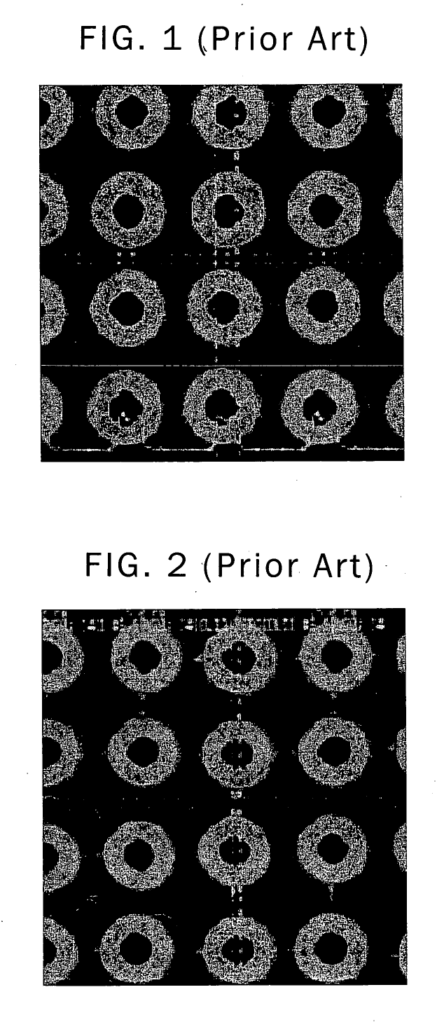

### DETAILED DESCRIPTIONS

Example embodiments of the present invention will be described with reference to the accompanying drawings. The present invention may, however, be embodied in many different forms and should not be construed as limited to the example embodiments set forth herein. Rather, the example embodiments are provided so that disclosure of the present invention will be thorough and complete, and will fully convey the scope of the present invention to those skilled in the art. The principles and features of this invention may be employed in varied and numerous embodiments without departing from the scope of the present invention. In the drawings, the sizes and relative sizes of layers and regions may be exaggerated for clarity. The drawings are not to scale. Like reference numerals refer to like elements throughout.

It will be understood that when an element or layer is referred to as being “on”, “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. As used herein, the term “and/or” may include any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Example embodiments of the present invention are described with reference to cross-section illustrations that are schematic illustrations of idealized embodiments of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and are not intended to limit the scope of the present invention.

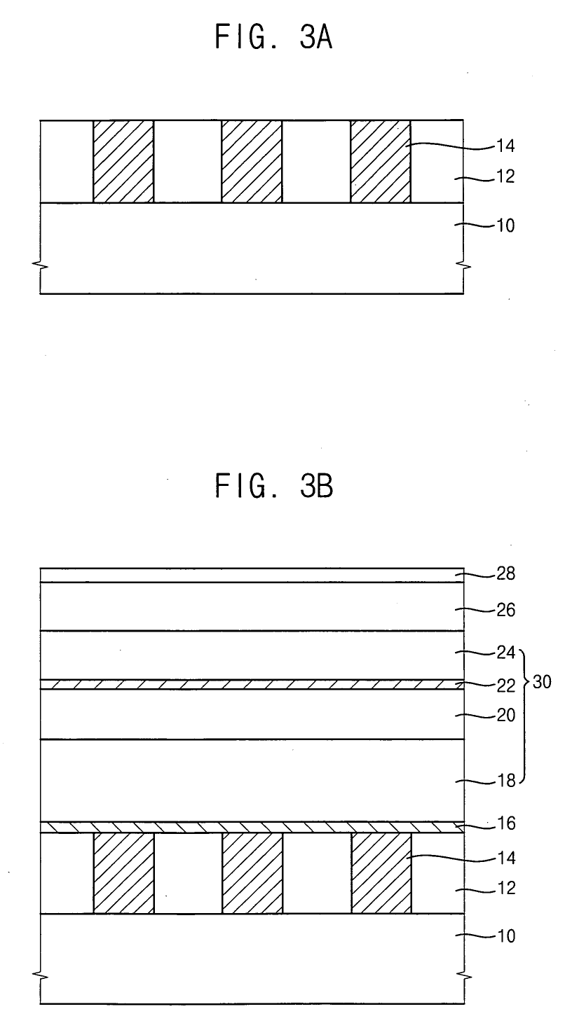

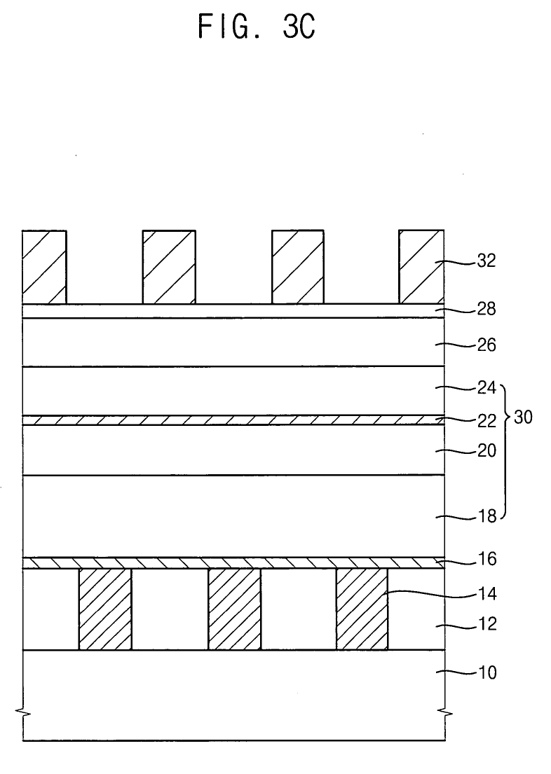

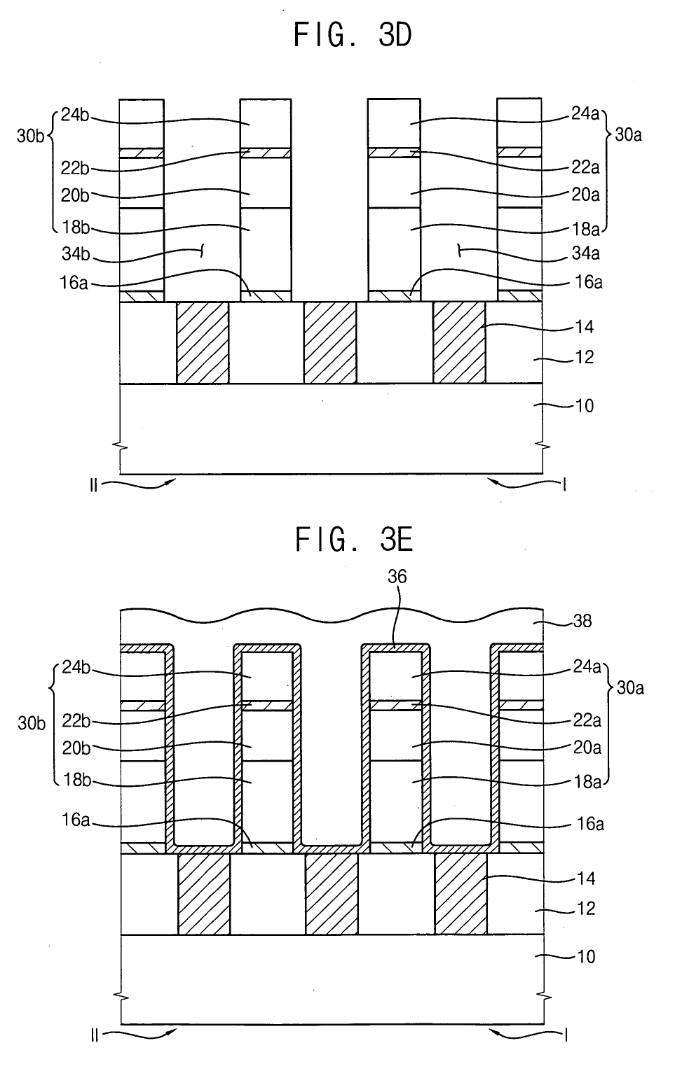

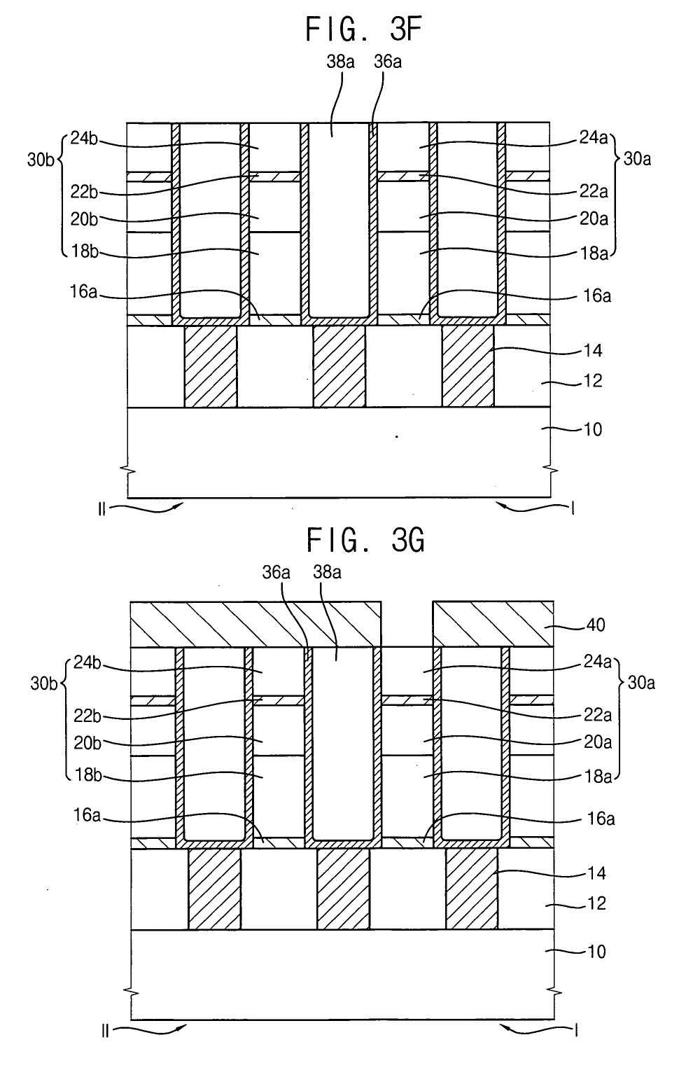

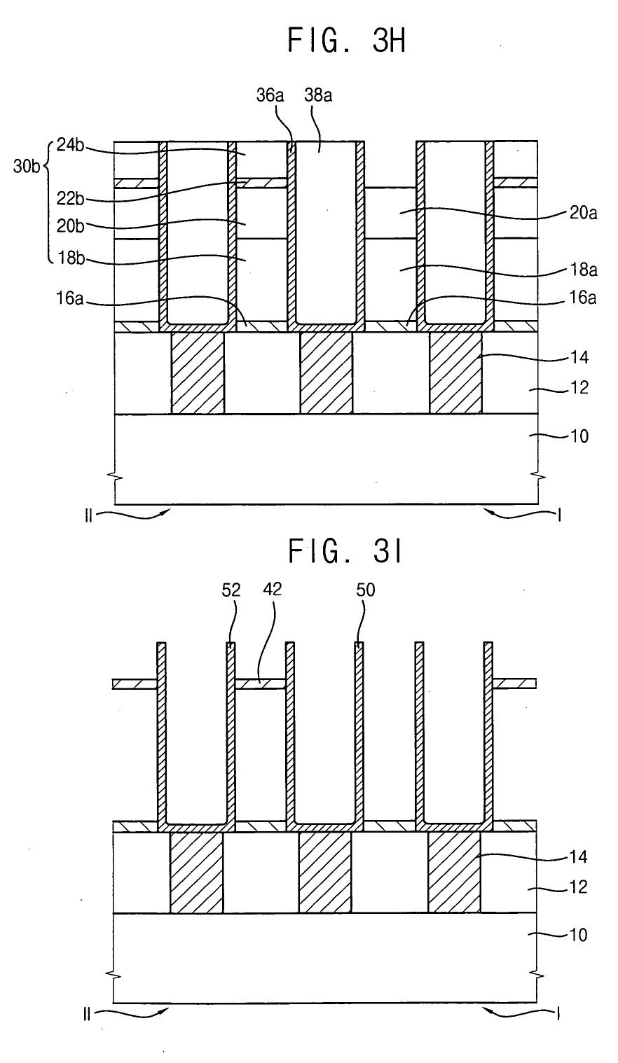

FIGS. 3A to 3I are cross-sectional views illustrating methods of manufacturing a semiconductor device in accordance with example embodiments of the present invention.

Referring to FIG. 3A, an isolation layer (not shown) is formed on a surface of a substrate 10. The substrate 10 may be, for example, a silicon substrate or a silicon-on-insulator (SOI) substrate. A lower structure (not shown) may be formed on the substrate 10. The lower structure may include a transistor that has a gate electrode. The semiconductor device may include a bit line. An insulation interlayer 12 having a contact plug 14 is formed on the substrate 10. The contact plug 14 may electrically contact a landing pad (not shown) formed between the gate electrodes of the transistors.

Referring to FIG. 3B, an etch stop layer 16 is formed on the insulation interlayer 12 having the contact plug 14. The etch stop layer 16 may be formed using an insulation material such as a nitride. In some example embodiments of the present invention, the etching stop layer 16 may be formed using a silicon nitride to a thickness of about 500 Å. A multi-layer structure 30 including a preliminary support layer 22 is formed on the etch stop layer 16. The multi-layer structure 30 may be used as a mold structure required for forming a lower electrode having a cylindrical shape.

The preliminary support layer 22 may be formed at a middle portion of the multi-layer structure 30. As one alternative, the preliminary support layer 22 may be formed at an upper portion of the multi-layer structure 30. As another alternative, the preliminary support layer 22 may be formed at a lower portion of the multi-layer structure 30. In order words, the preliminary support layer 22 may be formed at any portion of the multi-layer structure 30. In some example embodiments of the present invention, the multi-layer structure 30 may include a preliminary support layer pattern instead of the preliminary support layer 22.

The preliminary support layer 22 may be formed using an insulation material such as a nitride. In some example embodiments of the present invention, the preliminary support layer 22 may be formed using a silicon nitride. The multi-layer structure 30 may be formed using an insulation material such as an oxide. For example, the multi-layer structure 30 may include a borophosphosilicate glass (BPSG) layer and/or a tetraethyl orthosilicate (TEOS) layer. In some example embodiments of the present invention, an organic anti-reflective coating (ARC) layer 26 and a silicon oxynitride layer 28 are formed on the multi-layer structure 30. Because the organic anti-reflective coating layer 26 and the silicon oxynitride layer 28 are formed on the multi-layer structure 30, the efficiency of a photolithography process that is subsequently performed to form a photoresist pattern 32 (see FIG. 3C) may increase.

In some example embodiments of the present invention, the following materials can be sequentially formed on the etch stop layer 16 to form the multi-layer structure 30: a BPSG layer 18 having a thickness of about 12,000 Å, a lower TEOS layer 20 having a thickness of about 5,000 Å, the preliminary support layer 22 having a thickness of about 1,000 Å, an upper TEOS layer 24 having a thickness of about 5,000 Å, the organic anti-reflective coating layer 26 having a thickness of about 5,000 Å, and the silicon oxynitride layer 28 having a thickness of about 600 Å. The preliminary support layer 22 may include a silicon nitride.

Referring to FIG. 3C, the photoresist pattern 32 is formed on the silicon oxynitride layer 28 by the photolithography process. An etching process, using the photoresist pattern 32 as an etching mask, is performed on the silicon oxynitride layer 28, the organic anti-reflective coating layer 26, the upper TEOS layer 24, the preliminary support layer 22, the lower TEOS layer 20, the BPSG layer 18, and the etch stop layer 16. The etching process may be a dry etching process. After the etching process, the photoresist pattern and remaining portions of the organic anti-reflective coating layer 26 and the silicon oxynitride layer 28 are removed.

Referring to FIG. 3D, the multi-layer structure 30 including the preliminary support layer 22 may be patterned by the etching process so that a first pattern structure 30a and a second pattern structure 30b are formed.

Particularly, the first pattern structure 30a is formed over a first region (I) of the substrate 10. The first pattern structure 30a may be a multi-pattern structure including a first support layer pattern 22a. The first pattern structure 30a has a first opening 34a exposing the contact plug 14. The second pattern structure 30b may be a multi-pattern structure including a second support layer pattern 22b. The second pattern structure 30b is formed on a second region (II) of the substrate 10. The second pattern structure 30b has a second opening 34b exposing the contact plug 14. In detail, the first pattern structure 30a includes a first BPSG layer pattern 18a, a first lower TEOS layer pattern 20a, a first support layer pattern 22a and a first upper TEOS layer pattern 24a. The second pattern structure 30b includes a second BPSG layer pattern 18b, a second lower TEOS layer pattern 20b, a second support layer pattern 22b and a second upper TEOS layer pattern 24b.

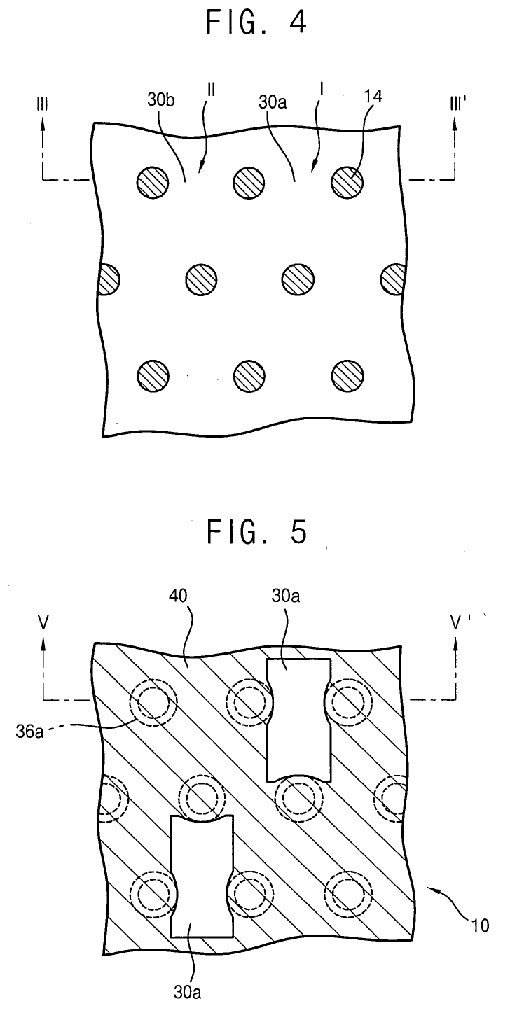

FIG. 4 is a plan view of FIG. 3D for illustrating the first region and the second region. That is, FIG. 3D is a cross-sectional view taken along line III-III′ in FIG. 4. Referring to FIGS. 3E-3H and 4-6, a portion of the first support layer pattern 22a, the portion being positioned over the first region (I), may be removed by a first etching process. A portion of the second support layer pattern 22b, the portion positioned over the second region (II) of the substrate 10, may partially remain after a second etching process to form a stabilizing member.

Referring to FIG. 3E, upper faces of the first and second pattern structures 30a and 30b and inner faces of the first and second openings 34a and 34b are uniformly covered with a conductive layer 36. The conductive layer 36 may be continuously formed. The conductive layer 36 may include a doped polysilicon, a metal, or a metal nitride. In some example embodiments of the present invention, the conductive layer 36 may include the doped polysilicon.

A sacrificial layer 38 is formed on the conductive layer 36. The conductive layer 36 and the sacrificial layer 38 together may fill the first opening 34a and the second opening 34b. The sacrificial layer 38 may be formed using an insulation material such as an oxide. In some example embodiments of the present invention, the sacrificial layer 38 may be formed using USG.

Referring to FIG. 3F, the sacrificial layer 38 and the conductive layer 36 are planarized by a planarization process until the first pattern structure 30a and the second pattern structure 30b are exposed, so that a sacrificial layer pattern 38a and a conductive layer pattern 36a may be formed. The planarization process may be a chemical mechanical polishing process or an etch-back process. These processes may be used alone or in combination. The conductive layer pattern 36a may include a first conductive layer pattern formed over the first region (I) and a second conductive layer pattern formed over the second region (II). In addition, the sacrificial layer pattern 38a may remain in the first and second openings 34a and 34b.

FIG. 5 is a plan view of FIG. 3G for illustrating a photoresist pattern used in a first etching process. That is, FIG. 3G is a cross-sectional view taken along line V-V′ in FIG. 5. Referring to FIGS. 3G and 5, a photoresist pattern 40 is formed on the conductive layer pattern 36a and the sacrificial layer pattern 38a. The photoresist pattern 40 exposes the first pattern structure 30a over the first region (I).

Referring to FIG. 3H, a first etching process using the photoresist pattern 40 as an etch mask is carried out. In particular, the first etching process is a dry etching process. The first etching process may be performed until the first upper TEOS layer pattern 24a and the first support layer pattern 22a are removed. When this first etching process is performed, the first BPSG layer pattern 18a and the first lower TEOS layer pattern 20a may remain over the first region (I). The first BPSG layer pattern 18a and the first lower TEOS layer pattern 20a may be then removed by a second etching process. Alternatively, the first BPSG layer pattern 18a and the first lower TEOS layer pattern 20a may be removed together with the first upper TEOS layer pattern 24a and the first support layer pattern 22a by the first etching process without performing the second etching process. In other words, the first pattern structure 30a is fully removed by the first etching process. Thereafter, the photoresist pattern 40 is removed.

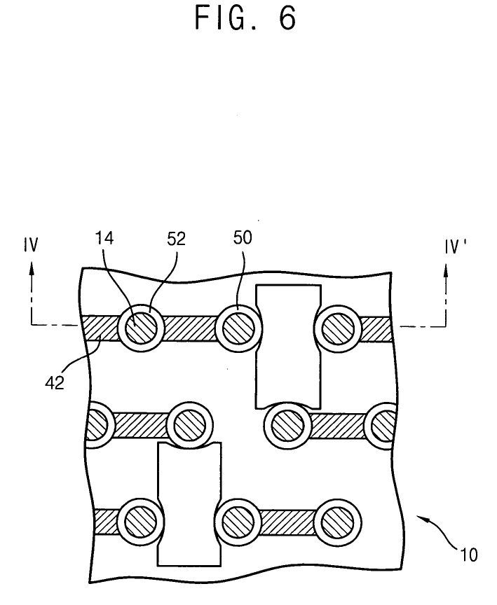

Referring to FIGS. 3I and 6, the second etching process is carried out. FIG. 6 is a plan view of FIG. 3I for illustrating a first lower electrode and a second lower electrode that is supported by a stabilizing member 42 as will be explained further below. FIG. 3I is a cross-sectional view taken along line VI-VI′ of FIG. 6.

The second etching process uses an etch selectivity, that is, a difference in etch rates, between, for example, a nitride included in the second support layer pattern 22b and an oxide included in the second BPSG layer pattern 18b, the lower TEOS layer pattern 20b and the second upper TEOS layer pattern 24b. In addition, in case that the first BPSG layer pattern 18a and the first lower TEOS layer pattern 20a are not removed by the first etching process, the first BPSG layer pattern 18a and the first lower TEOS layer pattern 20a may be removed by the second etching process. Furthermore, the sacrificial layer pattern 38a may be also removed by the second etching process. In some example embodiments of the present invention, etch rates of the second BPSG layer pattern 18b, the lower TEOS layer pattern 20b and the second upper TEOS layer pattern 24b are at least fifty times the etch rate of the second support layer pattern 22b. Thus, in some example embodiments of the present invention, a limulus amebocyte lysate (LAL) solution including hydrogen fluoride (HF), ammonium fluoride (NH₄F), and a DI-water may be used in the second etching process. When the LAL solution is used in the second etching process, the second support layer pattern 22b, the second BPSG layer pattern 18b, and the second lower TEOS layer pattern 20a may be etched at about 13 Å per minute, about 700 Å per minute and about 1,400 Å per minute, respectively.

As a result, a first lower electrode 50 and a second lower electrode 52 that have cylindrical shapes are formed over the substrate 10. In detail, the first lower electrode 50 corresponding to the conductive layer pattern 36a is formed over the first region (I) of the substrate 10. The second lower electrode 52 supported by the stabilizing member 42 corresponding to the second support layer pattern 22b is formed on the second region (II) of the substrate 10. The second lower electrode 52 corresponds to the conductive layer pattern 36a.

A dielectric layer and an upper electrode are subsequently formed on the first lower electrode 50 and the second lower electrode 52 using techniques well known to one of ordinary skill in the art to complete a capacitor.

In accordance with some example embodiments of the present invention, lower electrodes are formed over a semiconductor substrate. In accordance with some example embodiments of the present invention, a first etching process using a photoresist pattern as an etching mask as well as a second etching process using a difference in etch rates is partially performed to form the lower electrodes. Thus, damage to a stabilizing member formed by etching a support layer pattern may be efficiently reduced. It may be because the second etching process is performed on only some regions of the substrate rather than the entire substrate. In addition, because the stabilizing member has a relatively small area, a residue residing on the stabilizing member may be efficiently removed without relatively large damage to the stabilizing member unlike the prior art.

In accordance with some example embodiments of the present invention, a thickness of the stabilizing member formed over a central portion of the substrate may be substantially the same as that formed over a peripheral portion of the substrate. That is, a thickness uniformity of the stabilizing member may be relatively high. Furthermore, the stabilizing member supports the lower electrode in a predetermined region. Thus, the lower electrode may not easily lean or bend.

According to example embodiments of the present invention, a stabilizing member having a relatively high uniformity is formed over an entire substrate. Again, the lower electrode may not easily lean or bend. Thus, an electric reliability of a semiconductor device may be significantly improved.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of manufacturing a semiconductor device, the method comprising:
forming first and second multi-layer pattern structures over first and second regions of a substrate, respectively, the first and second multi-layer pattern structures including first and second support layer patterns, respectively, the first and second multi-layer pattern structures defining first and second openings that expose the first and second regions, respectively;
forming first and second liner patterns on an inner face of the first opening and an inner face of the second opening, respectively;
performing a first etching process on the first multi-layer pattern structure until the first support layer pattern is removed; and
performing a second etching process to remove the second multi-layer pattern structure except for the second support layer pattern.

2. The method of claim 1, wherein the first support layer pattern is positioned at an upper portion, a lower portion or middle portion of the first multi-layer pattern structure; and
wherein the second support layer pattern is positioned at an upper portion, a lower portion or a middle portion of the second multi-layer pattern structure.

3. The method of claim 1, wherein the first multi-layer pattern structure except for the first support layer pattern and the second multi-layer pattern structure except for the second support layer pattern comprise an oxide; and
wherein the first support layer pattern and the second support layer pattern comprise a nitride.

4. The method of claim 1, wherein the first and second liner patterns comprise a conductive material.

5. The method of claim 1, wherein forming the first and second liner patterns comprises:
forming first and second liners, the first liner over an upper face of the first multi-layer pattern structure and on the inner face of the first opening, the second liner over an upper face of the second multi-layer pattern structure and on the inner face of the second opening;
forming a sacrificial layer on the first and second liners; and
removing the sacrificial layer until the upper surfaces of the first and second multi-layer pattern structures are exposed.

6. The method of claim 5, wherein the sacrificial layer includes an oxide.

7. The method of claim 1, wherein the first etching process uses a photoresist pattern as an etch mask.

8. The method of claim 1, wherein during the second etching process, an etch rate of the second support layer pattern is different from an etch rate of the second multi-layer pattern structure except for the second support layer pattern.

9. The method of claim 8, wherein the etch rate of the second multi-layer pattern structure except for the second support layer pattern is at least about fifty times the etch rate of the second support layer pattern.

10. The method of claim 9, wherein the second etching process uses a limulus amebocyte lysate solution as an etching solution; and
wherein the limulus amebocyte lysate solution includes hydrogen fluoride, ammonium fluoride, and a DI-water.

11. The method of claim 1, further comprising removing residues of the first multi-layer pattern structure that remain after the first etching process during the second etching process.

12. A method of manufacturing a semiconductor device, the method comprising:
forming an insulation interlayer having a contact plug on a substrate having first and second regions;
forming a multi-layer structure having a preliminary support layer on the insulation interlayer;
patterning the multi-layer structure to form first and second multi-layer pattern structures over the first and second regions, respectively, the first and second multi-layer pattern structures having first and second support layer patterns, respectively, the first and second multi-layer pattern structures defining first and second openings that expose a portion of the first region and a portion of the second region, respectively;
forming a conductive layer over the first and second multi-layer pattern structures;
forming a sacrificial layer on the conductive layer;
removing the sacrificial layer until top surfaces of the first and second multi-layer pattern structures are exposed;
performing a first etching process on the first multi-layer pattern structure until the first support layer pattern is removed; and
performing a second etching process to remove the second pattern structure except for the second support layer pattern.

13. The method of claim 12, further comprising forming an etch stop layer on the insulation interlayer.

14. The method of claim 13, wherein the etch stop layer includes a nitride.

15. The method of claim 12, wherein the preliminary support layer is formed at an upper portion, a lower portion or a middle portion of the multi-layer structure.

16. The method of claim 12, wherein the preliminary support layer includes a nitride;
wherein the multi-layer structure except for the preliminary support layer includes an oxide; and
wherein the sacrificial layer includes an oxide.

17. The method of claim 12, wherein the conductive layer includes any one material selected from the group consisting of polysilicon, metal, and metal nitride.

18. The method of claim 12, wherein removing the sacrificial layer comprises a chemical mechanical polishing process.

19. The method of claim 12, wherein the first etching process uses a photoresist pattern as an etch mask.

20. The method of claim 12, wherein during the second etching process, an etch rate of the second support layer pattern is different from an etch rate of the second multi-layer pattern structure except for the second support layer pattern.

21. The method of claim 20, wherein the etch rate of the second multi-layer pattern structure except for the second support layer pattern is at least about fifty times the etch rate of the second support layer pattern.

22. The method of claim 12, further comprising removing residues of the first multi-layer pattern structure that remain after the first etching process during the second etching process.
